(19) United States
(12) Patent Application Publication
(10) Pub. No.: US 2024/0369742 A1
(43) Pub. Date: Nov. 7, 2024

(54) PLASMONIC-PHOTONIC CRYSTAL HYBRID NANOSTRUCTURES, AND METHODS OF MAKING AND USING THE SAME

(71) Applicant: Trustees of Tufts College, Medford, MA (US)

(72) Inventors: Fiorenzo G. Omenetto, Lexington, MA (US); Yu Wang, Nanjing (CN); Beom Joon Kim, Fremont, CA (US); Giulia Guidetti, Somerville, MA (US)

(21) Appl. No.: 18/651,846

(22) Filed: May 1, 2024

Related U.S. Application Data
(60) Provisional application No. 63/500,112, filed on May 4, 2023.

(51) Int. Cl. G02B 5/00; B82Y 20/00; C30B 29/60; G02B 1/00; G02B 6/122; G02F 1/035

(52) U.S. Cl. CPC G02B 5/008; B82Y 20/00; C30B 29/60; G02B 1/005; G02B 6/1225; G02F 1/035; G02B 2207/101; G02F 2202/32

(57) ABSTRACT

A plasmonic-photonic crystal hybrid nanostructure may include a protein-based inverse opal comprising at least 3 periodic inverse opal layers, the protein-based inverse opal having a opal face and a plasmonic face, wherein the plasmonic face is differentially etched between a first plasmonic region and a second plasmonic region, such that a top inverse opal layer of the at least 3 periodic inverse opal layers has a first etch phase in the first plasmonic region and a second etch phase in the second plasmonic region, wherein the first etch phase and the second etch phase are different. The nanostructure may include a plasmonic material layer deposited onto the plasmonic face.

### CROSS-REFERENCE TO RELATED APPLICATIONS

This application relates to, incorporates by reference for all purposes, and claims priority to U.S. Application Ser. No. 63/500,112, filed May 4, 2023.

### STATEMENT REGARDING FEDERALLY SPONSORED RESEARCH

This invention was made with government support under grant N00014-19-2399 awarded by the US Navy, Office of Naval Research. The government has certain rights in the invention.

### BACKGROUND

While hybrid plasmonic-photonic crystals are known in a broad sense, a challenge remains to combine multiple unique optical functions within a single platform by way of precise programming. A need exists for programmable nanostructures possessing these unique functions, which allow directional, tunable, and multiple optical effects by way of leveraging the physics and materials principles disclosed.

### SUMMARY

In some aspects, the techniques described herein relate to a plasmonic-photonic crystal hybrid nanostructure including: a protein-based inverse opal including at least 3 periodic inverse opal layers, the protein-based inverse opal having a opal face and a plasmonic face, wherein the plasmonic face is differentially etched between a first plasmonic region and a second plasmonic region, such that a top inverse opal layer of the at least 3 periodic inverse opal layers has a first etch phase in the first plasmonic region and a second etch phase in the second plasmonic region, wherein the first etch phase and the second etch phase are different; and a plasmonic material layer deposited onto the plasmonic face.

In some aspects, the techniques described herein relate to a method of making a plasmonic-photonic crystal hybrid nanostructure, the method including the following sequential steps: a) forming a colloidal crystal of a solidified protein having a plurality of nanoparticles embedded therein in a predefined opal structure including at least 3 periodic opal structure layers; b) masking the colloidal crystal leaving a first plasmonic region exposed and etching the colloidal crystal, thereby exposing a first etch phase of the colloidal crystal layer of the colloidal crystal in the first plasmonic region; c) optionally masking the colloidal crystal leaving a second plasmonic region exposed and optionally etching the colloidal crystal, thereby optionally exposing a second etch phase of the top colloidal crystal layer of the colloidal crystal in the second plasmonic region, wherein the second etch phase is different than the first etch phase; d) optionally masking the colloidal crystal leaving a third plasmonic region exposed and optionally etching the colloidal crystal, thereby optionally exposing a third etch phase of the top colloidal crystal layer of the colloidal crystal in the third plasmonic region, wherein the third etch phase is different than the first etch phase and the second etch phase; c) optionally masking the colloidal crystal leaving a fourth plasmonic region exposed and optionally etching the colloidal crystal, thereby optionally exposing a fourth etch phase of the top colloidal crystal layer of the colloidal crystal in the fourth plasmonic region, wherein the fourth etch phase is different than the first etch phase, the second etch phase, and the third etch phase; f) optionally depositing a layer of plasmonic material onto the top colloidal crystal layer of the colloidal crystal without depositing inside of an inverse opal layer; g) removing the plurality of nanoparticles from the colloidal crystal, thereby forming a protein-based inverse opal from the colloidal crystal, at least 3 inverse opal layers from the at least 3 colloidal crystal layers, and a top inverse opal layer from the top colloidal crystal layer; h) optionally masking the protein-based inverse opal leaving a first photonic region above a first photonic volume exposed and optionally bandgap tuning the protein-based inverse opal, thereby optionally producing a first tuned bandgap in the first bandgap volume; i) optionally masking the protein-based inverse opal leaving a second photonic region above a second photonic volume exposed and optionally bandgap tuning the protein-based inverse opal, thereby optionally producing a second tuned bandgap in the second bandgap volume; j) optionally masking the protein-based inverse opal leaving a third photonic region above a third photonic volume exposed and optionally bandgap tuning the protein-based inverse opal, thereby optionally producing a third tuned bandgap in the third bandgap volume; k) optionally masking the protein-based inverse opal leaving a fourth photonic region above a fourth photonic volume exposed and optionally bandgap tuning the protein-based inverse opal, thereby optionally producing a fourth tuned bandgap in the fourth bandgap volume; l) optionally depositing the layer of plasmonic material onto the protein-based inverse opal, thereby depositing the layer of plasmonic material inside of the inverse opals of the top inverse opal layer, wherein the method includes either the depositing of step f) or the depositing of step 1); m) optionally masking the protein-based inverse opal leaving the first photonic region above the first photonic volume exposed and optionally bandgap tuning the protein-based inverse opal, thereby optionally producing the first tuned bandgap in the first bandgap volume, wherein the method includes either the masking and bandgap tuning of step h) or the masking and bandgap tuning of step m); n) optionally masking the protein-based inverse opal leaving the second photonic region above the second photonic volume exposed and optionally bandgap tuning the protein-based inverse opal, thereby optionally producing the second tuned bandgap in the second bandgap volume; o) optionally masking the protein-based inverse opal leaving the third photonic region above the third photonic volume exposed and optionally bandgap tuning the protein-based inverse opal, thereby optionally producing the third tuned bandgap in the third bandgap volume; p) optionally masking the protein-based inverse opal leaving a fourth photonic region above a fourth photonic volume exposed and optionally bandgap tuning the protein-based inverse opal, thereby optionally producing a fourth tuned bandgap in the fourth bandgap volume, the method producing the plasmonic-photonic crystal hybrid nanostructure.

In some aspects, the techniques described herein relate to a method of using a plasmonic-photonic crystal hybrid nanostructure, the method including: at least partly immersing the plasmonic-photonic crystal hybrid nanostructure in a selected solvent, thereby altering an appearance of the plasmonic-photonic crystal hybrid nanostructure from at least one angle.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention.

FIG. 1 is a side view of a plasmonic-photonic crystal hybrid nanostructure, in accordance with aspects of the present disclosure.

FIG. 2 is a top view of a plasmonic-photonic crystal hybrid nanostructure, in accordance with aspects of the present disclosure.

FIG. 3 is a top view of a plasmonic-photonic crystal hybrid nanostructure, in accordance with aspects of the present disclosure.

FIG. 4 is a top view of a plasmonic-photonic crystal hybrid nanostructure, in accordance with aspects of the present disclosure.

FIG. 5 is a top view of a plasmonic-photonic crystal hybrid nanostructure, in accordance with aspects of the present disclosure.

FIG. 6 is a top view of a plasmonic-photonic crystal hybrid nanostructure, in accordance with aspects of the present disclosure.

FIG. 7 is a top view of a plasmonic-photonic crystal hybrid nanostructure, in accordance with aspects of the present disclosure.

FIG. 8 is a top view of a plasmonic-photonic crystal hybrid nanostructure, in accordance with aspects of the present disclosure.

FIG. 9 is a top view of a plasmonic-photonic crystal hybrid nanostructure, in accordance with aspects of the present disclosure.

FIG. 10 is a top view of a plasmonic-photonic crystal hybrid nanostructure, in accordance with aspects of the present disclosure.

FIG. 11 is a flowchart of an example method for making a plasmonic-photonic crystal hybrid nanostructure.

### DETAILED DESCRIPTION OF THE INVENTION

Before the present invention is described in further detail, it is to be understood that the invention is not limited to the particular embodiments described. It is also understood that the terminology used herein is for the purpose of describing particular embodiments only, and is not intended to be limiting. The scope of the present invention will be limited only by the claims. As used herein, the singular forms “a”, “an”, and “the” include plural embodiments unless the context clearly dictates otherwise.

Specific structures, devices, and methods relating to surface patterning are disclosed. It should be apparent to those skilled in the art that many additional modifications beside those already described are possible without departing from the inventive concepts. In interpreting this disclosure, all terms should be interpreted in the broadest possible manner consistent with the context. Variations of the term “comprising” should be interpreted as referring to elements, components, or steps in a non-exclusive manner, so the referenced elements, components, or steps may be combined with other elements, components, or steps that are not expressly referenced. Embodiments referenced as “comprising” certain elements are also contemplated as “consisting essentially of” and “consisting of” those elements. When two or more ranges for a particular value are recited, this disclosure contemplates all combinations of the upper and lower bounds of those ranges that are not explicitly recited. For example, recitation of a value of between 1 and 10 or between 2 and 9 also contemplates a value of between 1 and 9 or between 2 and 10.

As used herein, “silk fibroin” refers to silk fibroin protein whether produced by silkworm, spider, or other insect, or otherwise generated (Lucas et al., Adv. Protein Chem., 13:107-242 (1958)). Any type of silk fibroin can be used in different embodiments described herein. Silk fibroin produced by silkworms, such as Bombyx mori, is the most common and represents an earth-friendly, renewable resource. For instance, silk fibroin used in a silk film may be attained by extracting sericin from the cocoons of B. mori. Organic silkworm cocoons are also commercially available. There are many different silks, however, including spider silk (e.g., obtained from Nephila clavipes), transgenic silks, genetically engineered silks, such as silks from bacteria, yeast, mammalian cells, transgenic animals, or transgenic plants, and variants thereof, that can be used. See, e.g., WO 97/08315 and U.S. Pat. No. 5,245,012, each of which is incorporated herein by reference in their entireties.

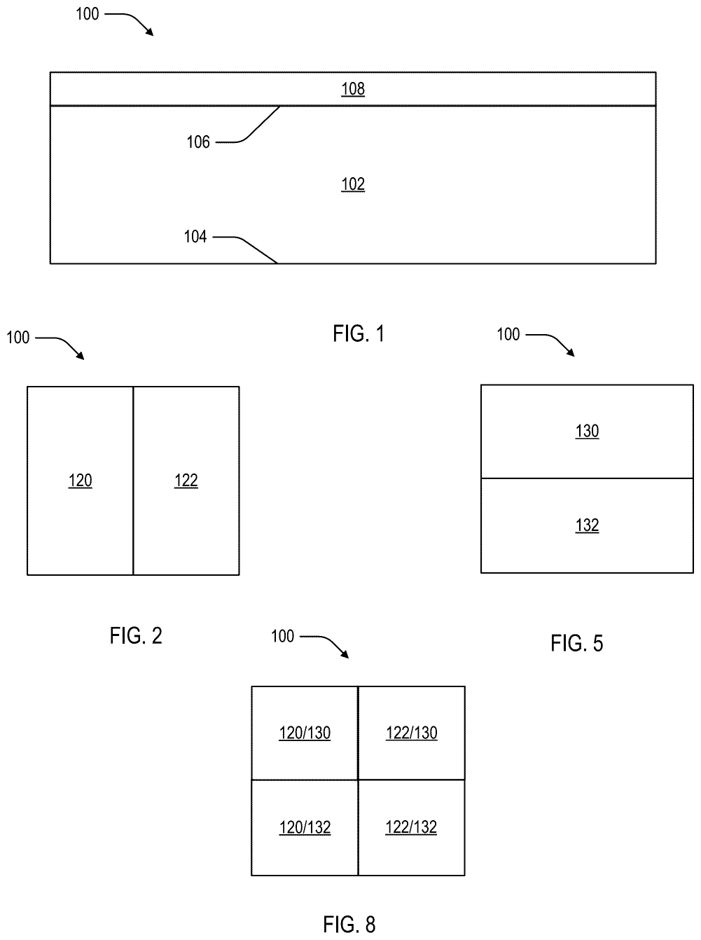

Referring to FIG. 1, a side view is shown of a plasmonic-photonic crystal hybrid nanostructure 100. The plasmonic-photonic crystal hybrid nanostructure 100 includes a protein-based inverse opal 102 having an opal face 104 and a plasmonic face 106 and a plasmonic material layer 108 deposited onto the plasmonic face 106.

The protein-based inverse silk opal 102 includes at least 3, at least 5, at least 7, at least 10, at least 15, at least 20, at least 25, at least 35, at least 40, or at least 50 periodic inverse opal layers. The protein-based inverse opal 102 can be a silk inverse opal, including inverse opals composed partly of silk fibroin, at least 50% by weight of silk fibroin, at least 90% by weight of silk fibroin, and substantially 100% by weight of silk fibroin.

A top inverse opal layer of the at least 3 periodic inverse opal layers has a first etch phase in the first plasmonic region 120 and a second etch phase in the second plasmonic region 122, wherein the first etch phase and the second etch phase are different.

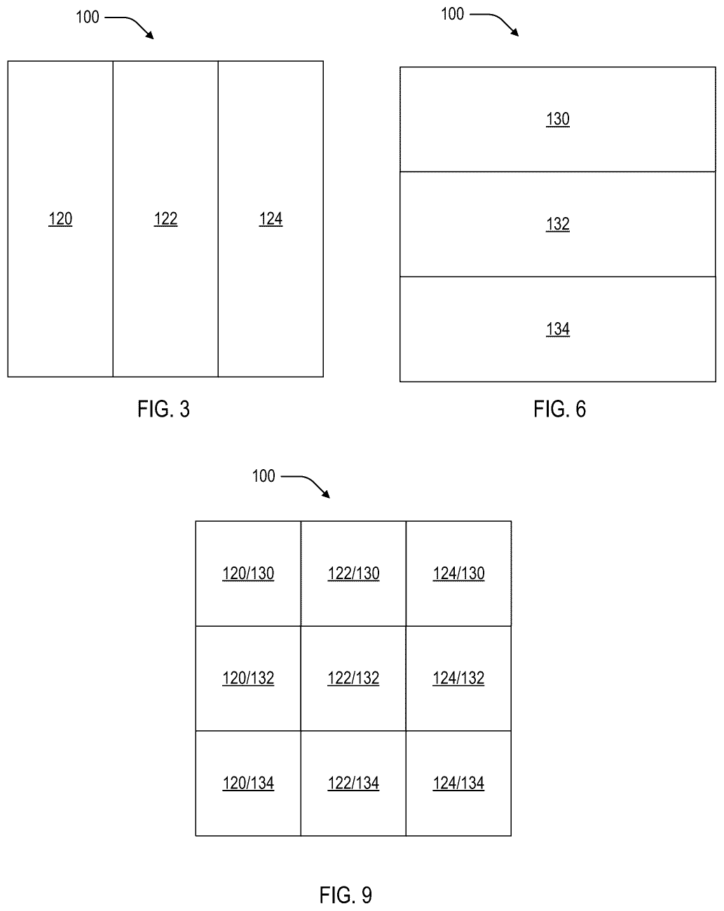

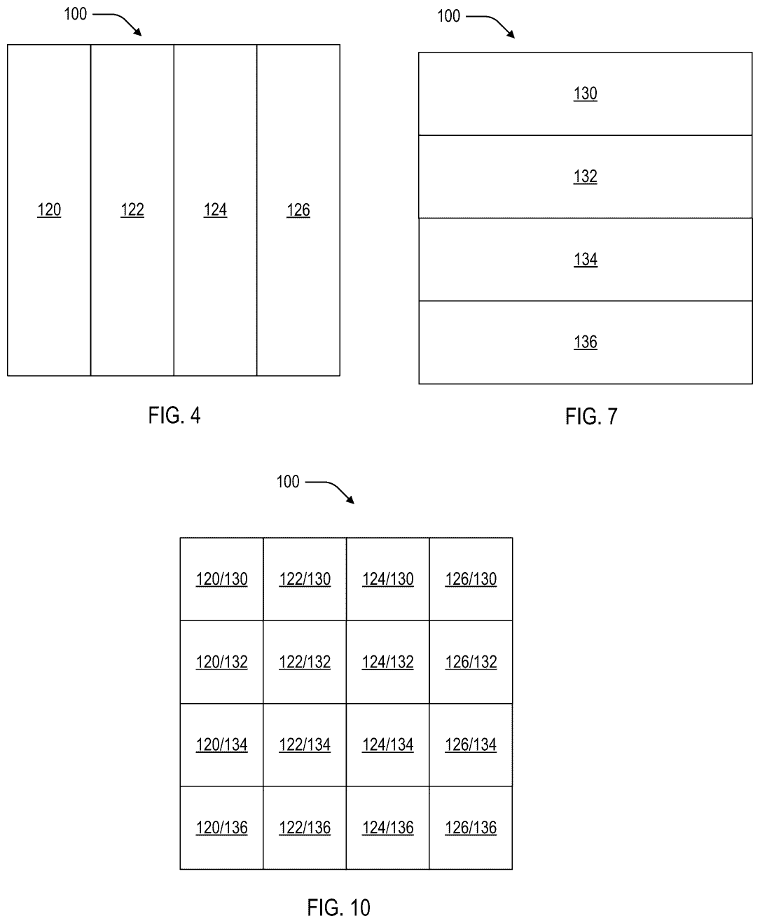

Referring to FIGS. 2-10, top views of various plasmonic-photonic crystal hybrid nanostructures 100 are illustrated, viewing from the direction of the plasmonic material layer 108 and the plasmonic face 106. Referring to FIG. 2, a plasmonic-photonic crystal hybrid nanostructure 100 with a first plasmonic region 120 and a second plasmonic region 122 is illustrated. Referring to FIG. 3, a plasmonic-photonic crystal hybrid nanostructure 100 with a first plasmonic region 120, a second plasmonic region 122, and a third plasmonic region 124 is illustrated. The top inverse opal layer of the at least 3 periodic inverse opal layers has a third etch phase in the third plasmonic region 124. Referring to FIG. 4, a plasmonic photonic crystal hybrid nanostructure 100 with a first plasmonic region 120, a second plasmonic region 122, a third plasmonic region 124, and a fourth plasmonic region 126 is illustrated. The top inverse opal layer of the at least 3 periodic inverse opal layers has a fourth etch phase in the fourth plasmonic region 126. A skilled artisan will recognize that this principle is extendable beyond the four regions that are expressly disclosed to five, six, seven, eight, or more regions and correspondingly unique etch phases.

The first plasmonic region 120, the second plasmonic region 122, the third plasmonic region 124, and/or the fourth plasmonic region 126 (or additional plasmonic region) can have any shape or size afforded by the masking and etching techniques or alternatives thereto which are deployed to generate the respective etch phases for the respective regions. Example 1 includes exemplary embodiments of a plasmonic-photonic crystal hybrid nanostructure with multiple plasmonic regions, as would be appreciated by a skilled artisan.

In some aspects, the techniques described herein relate to a plasmonic-photonic crystal hybrid nanostructure, wherein the first etch phase and/or the second etch phase and/or the third etch phase and/or the fourth etch phase and/or any additional etch phase provides a surface hole diameter of between 5 nm and 1000 nm.

Referring to FIG. 5, a plasmonic-photonic crystal hybrid nanostructure 100 with a first bandgap volume 130 and a second bandgap volume 132 is illustrated. Referring to FIG. 6, a plasmonic-photonic crystal hybrid nanostructure 100 with a first bandgap volume 130, a second bandgap volume 132, and a third bandgap volume 134 is illustrated. Referring to FIG. 7, a plasmonic photonic crystal hybrid nanostructure 100 with a first bandgap volume 130, a second bandgap volume 132, a third bandgap volume, 134, and a fourth bandgap volume 136 is illustrated.

The first bandgap volume 130, the second bandgap volume 132, the third bandgap volume 134, the fourth bandgap volume 136 can have any shape or size afforded by the masking and exposing techniques or alternatives thereto which are deployed to generate the respective bandgap shifts for the respective volumes. Example 1 includes exemplary embodiments of a plasmonic-photonic crystal hybrid nanostructure with multiple bandgap volumes, as would be appreciated by a skilled artisan.

Referring to FIG. 8-10, a plasmonic-photonic crystal hybrid nanostructure 100 is illustrated showing overlaps between the various regions and volumes. It should be appreciated that various numbers of regions and volumes can be combined to provide complex visual effects and/or encoding of optical signals.

In some aspects, the techniques described herein relate to a plasmonic-photonic crystal hybrid nanostructure, wherein the plasmonic face 106 is differentially etched between the first plasmonic region 120, the second plasmonic region 122, and a third plasmonic region 124, such that the top inverse opal layer of the at least 3 periodic inverse opal layers has a third etch phase in the third plasmonic region 124, wherein the third etch phase is different from the first etch phase and the second etch phase. In some aspects, the techniques described herein relate to a plasmonic-photonic crystal hybrid nanostructure, wherein the plasmonic face 106 is differentially etched between the first plasmonic region 120, the second plasmonic region 122, the third plasmonic region 124, and a fourth plasmonic region 126, such that the top inverse opal layer of the at least 3 periodic inverse opal layers has a fourth etch phase in the fourth plasmonic region 126, wherein the fourth etch phase is different from the first etch phase, the second etch phase, and the third etch phase.

As used herein, the term “etch phase” refers to the proportion of an inverse opal layer that is removed/exposed during an etching. A layer that has been etched to remove 5% of a layer has a different etch phase than the same layer having been etched to remove 50% of the layer. This differential etch phase can impact the properties of the eventually-deposited plasmonic material layer 108. In essence, the etch phase is a representation of the physical structure that results from the use of different etching times and/or different etching procedures to vertically remove different quantities of material from the colloidal crystal/inverse opal, thereby producing an optically different structure for each different etch phase.

In some aspects, the techniques described herein relate to a plasmonic-photonic crystal hybrid nanostructure, wherein the plasmonic material layer is selectively deposited outside inverse opals of the top inverse opal layer (i.e., the plasmonic material layer is deposited while the plurality of nanoparticles remains within the colloidal crystal, as described elsewhere herein). In some cases, the plasmonic material layer is deposited within inverse opals of the top inverse opal layer. In many cases, the plasmonic material layer is deposited both outside and within inverse opals of the top inverse opal layer. In some cases, the deposition extends beyond the top inverse opal layer and into deeper inverse opal layers of the protein-based inverse opal 102, such as a second inverse opal layer, a third inverse opal layer, or deeper.

In some aspects, the protein-based inverse opal 102 is differentially bandgap tuned between a first bandgap volume 130 and a second bandgap volume 132, such that the at least 3 periodic inverse opal layers have a first tuned bandgap in the first bandgap volume 130 and a second tuned bandgap in the second bandgap volume 132, wherein the first tuned bandgap and the second tuned bandgap are different. In some aspects, the protein-based inverse opal 102 is differentially bandgap tuned between the first bandgap volume 130, the second bandgap volume 132, and a third bandgap volume 134, such that the at least 3 periodic inverse opal layers have a third tuned bandgap in the third bandgap volume 134, wherein the third tuned bandgap is different than the first tuned bandgap and the second tuned bandgap. In some aspects, the protein-based inverse opal 102 is differentially bandgap tuned between the first bandgap volume 130, the second bandgap volume 132, the third bandgap volume 134, and a fourth bandgap volume 136, such that the at least 3 periodic inverse opal layers have a fourth tuned bandgap in the fourth bandgap volume 136, wherein the fourth tuned bandgap is different than the first tuned bandgap, the second tuned bandgap, and the third tuned bandgap.

In some aspects, the techniques described herein relate to a plasmonic-photonic crystal hybrid nanostructure, wherein the first bandgap volume 130 has a lateral periodicity of between 100 nm and 1500 nm and/or an interplanar spacing of between 50 nm and 1000 nm.

In some aspects, the techniques described herein relate to a plasmonic-photonic crystal hybrid nanostructure, wherein the top inverse opal layer has an inverse opal height of between 5 nm and 1000 nm.

In some aspects, the techniques described herein relate to a plasmonic-photonic crystal hybrid nanostructure, wherein the plasmonic material layer includes gold, silver, platinum, or a combination thereof. In some aspects, the techniques described herein relate to a plasmonic-photonic crystal hybrid nanostructure, wherein the plasmonic material layer includes gold.

In some aspects, the techniques described herein relate to a plasmonic-photonic crystal hybrid nanostructure, wherein the protein-based inverse opal 102 has a cubic close packed crystal structure. Other crystal structures are contemplated. In some cases, the etching to produce a given etch phase can expose a (111) face of the cubic close packed structure. Other exposed faces are contemplated.

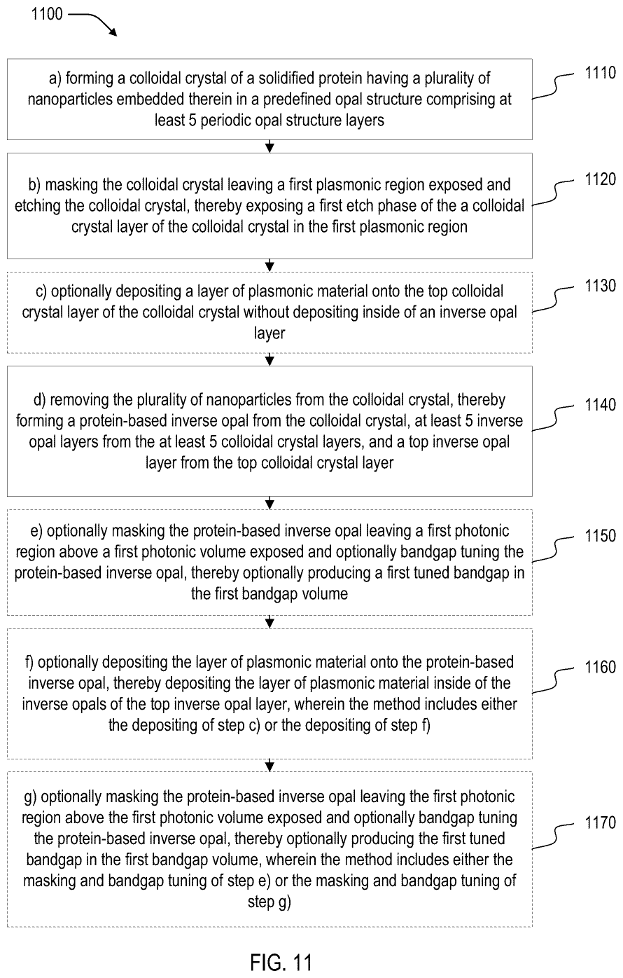

FIG. 11 is a flowchart of an example method for making a plasmonic-photonic crystal hybrid nanostructure. At step 1110, the method includes: a) forming a colloidal crystal of a solidified protein having a plurality of nanoparticles embedded therein in a predefined opal structure comprising at least 3 periodic opal structure layers. At step 1120, the method includes: b) masking the colloidal crystal leaving a first plasmonic region 120 exposed and etching the colloidal crystal, thereby exposing a first etch phase of the colloidal crystal layer of the colloidal crystal in the first plasmonic region 120. At step 1130, the method includes: c) optionally depositing a layer of plasmonic material onto the top colloidal crystal layer of the colloidal crystal without depositing inside of an inverse opal layer. At step 1140, the method includes: d) removing the plurality of nanoparticles from the colloidal crystal, thereby forming a protein-based inverse opal 102 from the colloidal crystal, at least 3 inverse opal layers from the at least 3 colloidal crystal layers, and a top inverse opal layer from the top colloidal crystal layer. At step 1150, the method includes: c) optionally masking the protein-based inverse opal 102 leaving a first photonic region above a first photonic volume exposed and optionally bandgap tuning the protein-based inverse opal 102, thereby optionally producing a first tuned bandgap in the first bandgap volume 130. At step 1160, the method includes: f) optionally depositing the layer of plasmonic material onto the protein-based inverse opal 102, thereby depositing the layer of plasmonic material inside of the inverse opals of the top inverse opal layer, wherein the method includes either the depositing of step c) or the depositing of step f). At step 1170, the method includes: g) optionally masking the protein-based inverse opal 102 leaving the first photonic region above the first photonic volume exposed and optionally bandgap tuning the protein-based inverse opal 102, thereby optionally producing the first tuned bandgap in the first bandgap volume 130, wherein the method includes either the masking and bandgap tuning of step c) or the masking and bandgap tuning of step g). The method produces the plasmonic-photonic crystal hybrid nanostructure.

The present disclosure provides a method of making a plasmonic-photonic crystal hybrid nanostructure. The method includes the following sequential steps: a) forming a colloidal crystal of a solidified protein having a plurality of nanoparticles embedded therein in a predefined opal structure including at least 3 periodic opal structure layers; b) masking the colloidal crystal leaving a first plasmonic region 120 exposed and etching the colloidal crystal, thereby exposing a first etch phase of the a colloidal crystal layer of the colloidal crystal in the first plasmonic region 120; c) optionally masking the colloidal crystal leaving a second plasmonic region 122 exposed and optionally etching the colloidal crystal, thereby optionally exposing a second etch phase of the top colloidal crystal layer of the colloidal crystal in the second plasmonic region 122, wherein the second etch phase is different than the first etch phase; d) optionally masking the colloidal crystal leaving a third plasmonic region 124 exposed and optionally etching the colloidal crystal, thereby optionally exposing a third etch phase of the top colloidal crystal layer of the colloidal crystal in the third plasmonic region 124, wherein the third etch phase is different than the first etch phase and the second etch phase; c) optionally masking the colloidal crystal leaving a fourth plasmonic region 126 exposed and optionally etching the colloidal crystal, thereby optionally exposing a fourth etch phase of the top colloidal crystal layer of the colloidal crystal in the fourth plasmonic region 126, wherein the fourth etch phase is different than the first etch phase, the second etch phase, and the third etch phase; f) optionally depositing a layer of plasmonic material onto the top colloidal crystal layer of the colloidal crystal without depositing inside of an inverse opal layer; g) removing the plurality of nanoparticles from the colloidal crystal, thereby forming a protein-based inverse opal 102 from the colloidal crystal, at least 3 inverse opal layers from the at least 3 colloidal crystal layers, and a top inverse opal layer from the top colloidal crystal layer; h) optionally masking the protein-based inverse opal 102 leaving a first photonic region above a first photonic volume exposed and optionally bandgap tuning the protein-based inverse opal 102, thereby optionally producing a first tuned bandgap in the first bandgap volume 130; i) optionally masking the protein-based inverse opal 102 leaving a second photonic region above a second photonic volume exposed and optionally bandgap tuning the protein-based inverse opal 102, thereby optionally producing a second tuned bandgap in the second bandgap volume 132; j) optionally masking the protein-based inverse opal 102 leaving a third photonic region above a third photonic volume exposed and optionally bandgap tuning the protein-based inverse opal 102, thereby optionally producing a third tuned bandgap in the third bandgap volume 134; k) optionally masking the protein-based inverse opal 102 leaving a fourth photonic region above a fourth photonic volume exposed and optionally bandgap tuning the protein-based inverse opal 102, thereby optionally producing a fourth tuned bandgap in the fourth bandgap volume 136; l) optionally depositing the layer of plasmonic material onto the protein-based inverse opal 102, thereby depositing the layer of plasmonic material inside of the inverse opals of the top inverse opal layer, wherein the method includes either the depositing of step f) or the depositing of step 1l; m) optionally masking the protein-based inverse opal 102 leaving the first photonic region above the first photonic volume exposed and optionally bandgap tuning the protein-based inverse opal 102, thereby optionally producing the first tuned bandgap in the first bandgap volume 130, wherein the method includes either the masking and bandgap tuning of step h) or the masking and bandgap tuning of step m); n) optionally masking the protein-based inverse opal 102 leaving the second photonic region above the second phonic volume exposed and optionally bandgap tuning the protein-based inverse opal 102, thereby optionally producing the second tuned bandgap in the second bandgap volume 132; o) optionally masking the protein-based inverse opal 102 leaving the third photonic region above the third photonic volume exposed and optionally bandgap tuning the protein-based inverse opal 102, thereby optionally producing the third tuned bandgap in the third bandgap volume 134; p) optionally masking the protein-based inverse opal 102 leaving a fourth photonic region above a fourth photonic volume exposed and optionally bandgap tuning the protein-based inverse opal 102, thereby optionally producing a fourth tuned bandgap in the fourth bandgap volume 136, the method producing the plasmonic-photonic crystal hybrid nanostructure.

In some aspects, the techniques described herein relate to a method, the method including: f) depositing the layer of plasmonic material onto the top colloidal crystal layer of the colloidal crystal without depositing inside of an inverse opal layer.

In some aspects, the techniques described herein relate to a method, the method including: h) masking the protein-based inverse opal 102 leaving the first photonic region above the first photonic volume exposed and bandgap tuning the protein-based inverse opal 102, thereby producing the first tuned bandgap in the first bandgap volume 130; and l) depositing the layer of plasmonic material onto the protein-based inverse opal 102, thereby depositing the layer of plasmonic material inside of the inverse opals of the top inverse opal layer.

In some aspects, the techniques described herein relate to a method, the method including: l) depositing the layer of plasmonic material onto the protein-based inverse opal 102, thereby depositing the layer of plasmonic material inside of the inverse opals of the top inverse opal layer; and m) masking the protein-based inverse opal 102 leaving the first photonic region above the first photonic volume exposed and bandgap tuning the protein-based inverse opal 102, thereby producing the first tuned bandgap in the first bandgap volume 130.

Bandgap tuning can be performed by methods understood to those having ordinary skill in the art to be suitable for tuning the bandgap of the protein-based inverse opal 102, including but not limited to, water-vapor exposure, methanol exposure (or other means of inducing formation of beta sheet crystal structure), or the like. In some cases, bandgap tuning involves inducing formation of beta sheet crystal structure in silk fibroin. In some cases, bandgap tuning involves water-vapor exposure.

In some aspects, the techniques described herein relate to a method, wherein the plasmonic material layer includes gold, silver, platinum, or a combination thereof. In some cases, the plasmonic material layer includes gold or is entirely composed of gold. In some aspects, the techniques described herein relate to a method, wherein the solidified protein includes silk fibroin.

The physics principles described in Example I will determine the ultimate image and color provided by the plasmonic-photonic crystal hybrid nanostructure. In some cases, one prominent image is visible from the plasmonic surface. In some cases, one prominent image appears in a reflection geometry and a different prominent image appears in transmission geometry. In some cases, one prominent reflection image is present in air and a different prominent reflection image is present when submerged in a solvent. In some cases, the image created by the plasmonic material may be visible from the plasmonic surface and reduced visibility from the opal side while in air, and the image created by the plasmonic material may be reduced visibility from the plasmonic side and clearly visible from the opal side while immersed in a solvent, such as isopropyl alcohol. In some cases, the visual effect or the color can be adjusted by adjusting viewing angle.

In another aspect, the present disclosure provides a method of using a plasmonic-photonic crystal hybrid nanostructure, as disclosed herein. The method includes at least partly immersing the plasmonic-photonic crystal hybrid nanostructure in a selected solvent. The immersing thereby alters an appearance of the plasmonic-photonic crystal hybrid nanostructure from at least one angle. The solvent can be isopropyl alcohol.

All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

All references, including publications, patent applications, and patents, cited herein are hereby incorporated by reference to the same extent as if each reference were individually and specifically indicated to be incorporated by reference and were set forth in its entirety herein.

Preferred aspects of this invention are described herein, including the best mode known to the inventors for carrying out the invention. Variations of those preferred aspects may become apparent to those of ordinary skill in the art upon reading the foregoing description. The inventors expect a person having ordinary skill in the art to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

While the invention has been illustrated and described in detail in the foregoing drawings and description, the same is to be considered as illustrative and not restrictive in character, it being understood that only illustrative embodiments thereof have been shown and described and that all changes and modifications that come within the spirit of the invention are desired to be protected. For example, any of the features or functions of any of the embodiments disclosed herein may be incorporated into any of the other embodiments disclosed herein.

### EXAMPLES

### Example 1

The following publication contains Example 1 and is incorporated herein by reference in its entirety, including supporting information and supplemental movies 1-5, for all purposes: Wang Y, Kim B J, Guidetti G, Omenetto F G. Generation of Complex Tunable Multispectral Signatures with Reconfigurable Protein-Based, Plasmonic-Photonic Crystal Hybrid Nanostructures. Small. 2022 June;18 (22): e2201036. doi: 10.1002/sml1.202201036. Epub 2022 May 8. PMID: 35527342.

For the avoidance of doubt, Supporting Information for Small, DOI: 10.1002/smll.202201036 is incorporated herein by references in its entirety for all purposes.

For the avoidance of doubt, the supplemental movies 1-5 included in the supporting information for Small, DOI: 10.1002/smll.202201036 are incorporated herein by reference in their entireties for all purposes.

I/We claim:

1. A plasmonic-photonic crystal hybrid nanostructure comprising:
a protein-based inverse opal comprising at least 3 periodic inverse opal layers, the protein-based inverse opal having a opal face and a plasmonic face, wherein the plasmonic face is differentially etched between a first plasmonic region and a second plasmonic region, such that a top inverse opal layer of the at least 3 periodic inverse opal layers has a first etch phase in the first plasmonic region and a second etch phase in the second plasmonic region, wherein the first etch phase and the second etch phase are different; and
a plasmonic material layer deposited onto the plasmonic face.

2. The plasmonic-photonic crystal hybrid nanostructure of claim 1, wherein the protein-based inverse opal is a silk inverse opal.

3. The plasmonic-photonic crystal hybrid nanostructure of claim 1, wherein the plasmonic face is differentially etched between the first plasmonic region, the second plasmonic region, and a third plasmonic region, such that the top inverse opal layer of the at least 3 periodic inverse opal layers has a third etch phase in the third plasmonic region, wherein the third etch phase is different from the first etch phase and the second etch phase.

4. The plasmonic-photonic crystal hybrid nanostructure of claim 3, wherein the plasmonic face is differentially etched between the first plasmonic region, the second plasmonic region, the third plasmonic region, and a fourth plasmonic region, such that the top inverse opal layer of the at least 3 periodic inverse opal layers has a fourth etch phase in the fourth plasmonic region, wherein the fourth etch phase is different from the first etch phase, the second etch phase, and the third etch phase.

5. The plasmonic-photonic crystal hybrid nanostructure of claim 1, wherein the plasmonic material layer is selectively deposited outside of inverse opals of the top inverse opal layer.

6. The plasmonic-photonic crystal hybrid nanostructure of claim 1, wherein the plasmonic material layer is deposited within inverse opals of the top inverse opal layer.

7. The plasmonic-photonic crystal hybrid nanostructure of claim 1, wherein the first etch phase and/or the second etch phase provides a surface hole diameter of between 5 nm and 1000 nm.

8. The plasmonic-photonic crystal hybrid nanostructure of claim 1, wherein the protein-based inverse opal is differentially bandgap tuned between a first bandgap volume and a second bandgap volume, such that the at least 3 periodic inverse opal layers have a first tuned bandgap in the first bandgap volume and a second tuned bandgap in the second bandgap volume, wherein the first tuned bandgap and the second tuned bandgap are different.

9. The plasmonic-photonic crystal hybrid nanostructure of claim 8, wherein the protein-based inverse opal is differentially bandgap tuned between the first bandgap volume, the second bandgap volume, and a third bandgap volume, such that the at least 3 periodic inverse opal layers have a third tuned bandgap in the third bandgap volume, wherein the third tuned bandgap is different than the first tuned bandgap and the second tuned bandgap.

10. The plasmonic-photonic crystal hybrid nanostructure of claim 9, wherein the protein-based inverse opal is differentially bandgap tuned between the first bandgap volume, the second bandgap volume, the third bandgap volume, and a fourth bandgap volume, such that the at least 3 periodic inverse opal layers have a fourth tuned bandgap in the fourth bandgap volume, wherein the fourth tuned bandgap is different than the first tuned bandgap, the second tuned bandgap, and the third tuned bandgap.

11. The plasmonic-photonic crystal hybrid nanostructure of claim 8, wherein the first bandgap volume has a lateral periodicity of between 100 nm and 1500 nm and/or an interplanar spacing of between 50 nm and 1000 nm.

12. The plasmonic-photonic crystal hybrid nanostructure of claim 1, wherein the top inverse opal layer has an inverse opal height of between 5 nm and 1000 nm.

13. The plasmonic-photonic crystal hybrid nanostructure of claim 1, wherein the plasmonic material layer comprises gold.

14. The plasmonic-photonic crystal hybrid nanostructure of claim 1, wherein the protein-based inverse opal has a cubic close packed crystal structure.

15. A method of making a plasmonic-photonic crystal hybrid nanostructure, the method comprising the following sequential steps:
a) forming a colloidal crystal of a solidified protein having a plurality of nanoparticles embedded therein in a predefined opal structure comprising at least 3 periodic opal structure layers;
b) masking the colloidal crystal leaving a first plasmonic region exposed and etching the colloidal crystal, thereby exposing a first etch phase of the colloidal crystal layer of the colloidal crystal in the first plasmonic region;
c) optionally depositing a layer of plasmonic material onto the top colloidal crystal layer of the colloidal crystal without depositing inside of an inverse opal layer;
d) removing the plurality of nanoparticles from the colloidal crystal, thereby forming a protein-based inverse opal from the colloidal crystal, at least 3 inverse opal layers from the at least 3 colloidal crystal layers, and a top inverse opal layer from the top colloidal crystal layer;
e) optionally masking the protein-based inverse opal leaving a first photonic region above a first photonic volume exposed and optionally bandgap tuning the protein-based inverse opal, thereby optionally producing a first tuned bandgap in the first bandgap volume;
f) optionally depositing the layer of plasmonic material onto the protein-based inverse opal, thereby depositing the layer of plasmonic material inside of the inverse opals of the top inverse opal layer, wherein the method includes either the depositing of step c) or the depositing of step f); and
g) optionally masking the protein-based inverse opal leaving the first photonic region above the first photonic volume exposed and optionally bandgap tuning the protein-based inverse opal, thereby optionally producing the first tuned bandgap in the first bandgap volume, wherein the method includes either the masking and bandgap tuning of step e) or the masking and bandgap tuning of step g);
the method producing the plasmonic-photonic crystal hybrid nanostructure.

16. The method of claim 15, the method comprising: f) depositing the layer of plasmonic material onto the top colloidal crystal layer of the colloidal crystal without depositing inside of an inverse opal layer.

17. The method of claim 15, the method comprising: h) masking the protein-based inverse opal leaving the first photonic region above the first photonic volume exposed and bandgap tuning the protein-based inverse opal, thereby producing the first tuned bandgap in the first bandgap volume; and l) depositing the layer of plasmonic material onto the protein-based inverse opal, thereby depositing the layer of plasmonic material inside of the inverse opals of the top inverse opal layer.

18. The method of claim 15, the method comprising: l) depositing the layer of plasmonic material onto the protein-based inverse opal, thereby depositing the layer of plasmonic material inside of the inverse opals of the top inverse opal layer; and m) masking the protein-based inverse opal leaving the first photonic region above the first photonic volume exposed and bandgap tuning the protein-based inverse opal, thereby producing the first tuned bandgap in the first bandgap volume.

19. The method of claim 15, wherein the plasmonic material layer comprises gold.

20. A method of using a plasmonic-photonic crystal hybrid nanostructure, the method comprising:
at least partly immersing the plasmonic-photonic crystal hybrid nanostructure in a selected solvent, thereby altering an appearance of the plasmonic-photonic crystal hybrid nanostructure from at least one angle.
